(19) United States
(12) Patent Application Publication
(10) Pub. No.: US 2007/0215907 A1
(43) Pub. Date: Sep. 20, 2007

(54) Semiconductor chip for producing a controllable frequency

(76) Inventors: Gerald Krimmer, Heilbronn (DE); Reinhard Reimann, Heilbronn (DE)

Correspondence Address: MCGRATH, GEISSLER, OLDS & RICHARDSON, PLLC, P.O. BOX 1364, FAIRFAX, VA, 22038-1364, US

(21) Appl. No.: 11/513,282

(22) Filed: Aug. 31, 2006

(30) Foreign Application Priority Data
Sep. 1, 2005 (DE) DE10 2005 042 706

(51) Int. Cl. H01L 27/10

(52) U.S. Cl. 257/206

(57) ABSTRACT

A semiconductor chip for producing a controllable frequency is disclosed, for example in transceivers. The semiconductor chip includes a voltage-controlled oscillator located in a first chip region of the semiconductor chip, a heat source, in particular in the form of a power amplifier and/or in the form of a phase-locked loop, that is located in a second chip region of the semiconductor chip, and contacts for contacting the semiconductor chip in a bonding process. At least a part of the contacts is located between the first and second chip regions in such a manner that it functions as thermal shielding between the first and second chip regions.

This nonprovisional application claims priority under 35 U.S.C. § 119(a) on German Patent Application No. DE 102005042706, which was filed in Germany on Sep. 1, 2005, and which is herein incorporated by reference.

### BACKGROUND OF THE INVENTION

1. Field of the Invention

The present invention relates to a semiconductor chip for producing a controllable frequency.

2. Description of the Background Art

Semiconductor chips are also called “die” or “dice.” They are typically obtained from a wafer by a singulation step. To produce the finished integrated circuit, electrically conductive contacts of the semiconductor chip are connected to associated contacts of a housing or substrate in what is called a bonding process. A packaging process may follow.

When such a semiconductor chip serves in its completed state to produce a controllable frequency, for example in what is called a transmitter/receiver or transceiver, it is usual to provide a voltage-controlled oscillator (VCO), which is arranged or implemented in a specific first area of the semiconductor chip.

To implement the transceiver function additional circuit components, however, are necessary, for example a power amplifier and/or a phase-locked loop (PLL), which are typically arranged in a region of the semiconductor chip adjacent to the first chip area, since close functional couplings exist between the circuit components.

The VCO is typically sensitive to temperature variations, i.e. the frequency it outputs depends on its temperature. Since the PLL or the power amplifier produces a significant amount of thermal power in operation, a disruptive effect on VCO operation can take place as a result of a thermal coupling between the different chip regions. This effect is disruptive especially when time slot methods are used so the VCO and the heat sources are each operated only briefly, thus resulting in a continuous cycle of heating and cooling.

In order to reduce these thermal effects, as large a distance as possible can be chosen between the heat source or heat sources and the VCO or the heat-sensitive circuit component. However, since chip areas are steadily becoming smaller and high operating frequencies require short distances between the coupled circuit components, the decoupling effects that can be achieved in this way are frequently unsatisfactory.

### SUMMARY OF THE INVENTION

It is therefore an object of the present invention to provide a semiconductor chip for producing a controllable frequency in which the disruptive thermal coupling between the chip region with a heat source and the chip region of the voltage-controlled oscillator is as small as possible.

According to an embodiment of the invention, at least a part of the contacts is located between a first and second chip region in such a manner that this part functions as a complete or at least partial thermal shield between the first and second chip regions. The contacts form a thermal sink into which the heat produced by the heat source can flow, thus not entering the chip region of the voltage-controlled oscillator at all or only to a small degree. In this way, a disruptive effect from the heat-generating circuit components can be effectively reduced or prevented.

In a further embodiment, the at least one part of the contacts serves to electrically contact the voltage-controlled oscillator. This permits simple layout of the chip and simple assignment to contacts of the substrate or the case.

In a further embodiment, the semiconductor chip can have the shape of a rectangle in a top view, and the first chip region can be located in the region of a corner of the rectangle. Such an arrangement permits a best possible decoupling from the heat source or sources, since the edge location of the first chip region minimizes an entry of heat caused by the heat sources.

In a further embodiment, the frequency can be in a region from 5 GHz to 7 GHz. Preferably, the frequency is at 5.8 GHz.

In a further embodiment, the semiconductor chip is an ISM transceiver. The ISM band (industrial, scientific, and medical band) is a frequency region for communication devices in industry, science and medicine. A uniform location for the ISM bands is not set worldwide. So, for example, there are ISM bands in the frequency regions of 902 MHz-928 MHz, 2,400 MHz-2,483.5 MHz, and 5,800 MHz, with only the 2.4 GHz band being approved worldwide.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a semiconductor chip for producing a controllable frequency according to an embodiment of the present invention; and

FIG. 2 shows a semiconductor chip for producing a controllable frequency according to another embodiment of the present invention.

### DETAILED DESCRIPTION

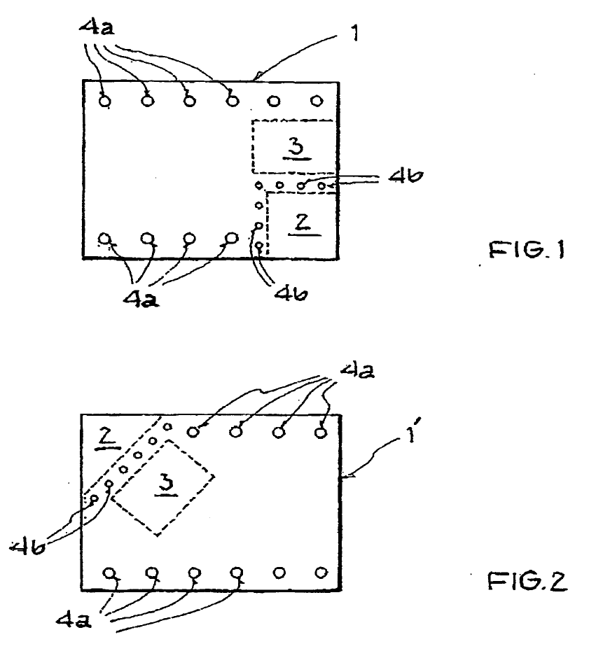

FIG. 1 shows a first embodiment of a rectangular semiconductor chip 1 for producing a controllable frequency. After a bonding process and packaging, it serves as an integrated circuit with an ISM transceiver function.

The semiconductor chip 1 includes a voltage-controlled oscillator that is located in a first chip region 2 in the lower right corner of the semiconductor chip 1, a heat source—in the form of a power amplifier and phase-locked loop—that is located in a second chip region 3 of the semiconductor chip 1 adjacent to the chip region 2, and multiple metallic contacts 4a and 4b for contacting the semiconductor chip 1 in a bonding process. The contacts 4a and 4b are shown only schematically in number, shape and dimensions. Of course, the semiconductor chip 1 can also include other functional units or circuit components that are not shown.

The contacts 4b that are associated with the voltage-controlled oscillator are arranged between the first and second chip regions 2 and 3 along two intersecting lines that are perpendicular to one another, in such a manner as to result in a thermal decoupling between the first and second chip regions 2 and 3. Heat energy arising in the second chip region 3 can flow through the contacts 4b without causing a significant heating of the first chip region 2. A so-called frequency drift of the VCO as a result of an activation or deactivation of the heat source is thus effectively prevented.

Additional connections for the integrated circuit are associated with the contacts 4a. Alternatively, of course, these contacts can also be used in addition or exclusively for thermal decoupling. The contacts 4a are located along the top and bottom horizontal edge of the semiconductor chip 1.

FIG. 2 shows a second alternative embodiment of a rectangular semiconductor chip 1′ for producing a controllable frequency. The semiconductor chip 1′ corresponds to the semiconductor chip 1 from FIG. 1 except for its altered topography.

The first chip region 2 is located in the top left corner of the semiconductor chip 1′, and the second chip region 3 is located adjacent to the chip region 2.

The contacts 4b that are associated with the voltage-controlled oscillator are arranged between the first and second chip regions along a diagonal line angled at approximately 450 to the horizontal from a left vertical edge to a top horizontal edge of the semiconductor chip 1′. This contact arrangement also results in an effective thermal decoupling of the chip regions 2 and 3.

Of course, almost any desired topography is possible in addition to the embodiments shown; the only important factor is that a thermal decoupling takes place based on an arrangement of contacts between the two regions to be decoupled.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A semiconductor chip for producing a controllable frequency, the semiconductor chip comprising:
a voltage-controlled oscillator provided in a first chip region of the semiconductor chip;
a heat source that is a power amplifier and/or a phase-locked loop, the heat source being provided in a second chip region of the semiconductor chip; and
a plurality of contacts for contacting the semiconductor chip in a bonding process, at least a portion of the contacts being provided between the first and second chip regions so that a thermal shielding between the first and second chip regions occurs.

2. The semiconductor chip according to claim 1, wherein the at least a portion of the contacts electrically contact the voltage-controlled oscillator.

3. The semiconductor chip according to claim 1, wherein the semiconductor chip is rectangular, and the first chip region is located in a corner thereof.

4. The semiconductor chip according to claim 1, wherein a frequency of the semiconductor chip is in a range from 5 GHz to 7 GHz.

5. The semiconductor chip according to claim 1, wherein the semiconductor chip is an ISM transceiver.
